(19) United States
(12) Patent Application Publication
(10) Pub. No.: US 2009/0284136 A1
(43) Pub. Date: Nov. 19, 2009

(54) ORGANIC LIGHT-EMISSION DEVICE

(75) Inventor: Yukinori KAWAMURA, Matsumoto City (JP)

Correspondence Address: ROSSI, KIMMS & McDOWELL LLP., 20609 Gordon Park Square, Suite 150, Ashburn, VA, 20147, US

(73) Assignee: FUJI ELECTRIC HOLDINGS CO., LTD., Kawasaki (JP)

(21) Appl. No.: 12/425,935

(22) Filed: Apr. 17, 2009

(30) Foreign Application Priority Data
Apr. 17, 2008 (JP) 2008-107826

(51) Int. Cl. H01J 1/63; H01L 21/00

(52) U.S. Cl. 313/504; 438/22; 257/E21.002

(57) ABSTRACT

A method is disclosed for producing a top-emitting organic light emitting diode device containing a substrate having provided thereon at least a lower electrode, an organic layer containing a light-emission layer, and an upper transparent electrode. Also disclosed is the top-emitting organic light emitting diode device produced by the method. The method include the steps of first forming the organic layer, then forming a metallic thin layer capable of forming a transparent electroconductive oxide, and finally oxidizing the metallic thin layer on formation of the upper transparent electrode.

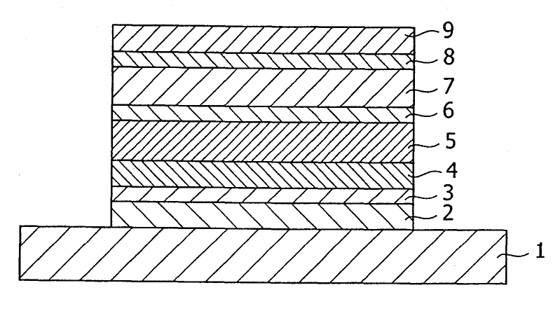

### BACKGROUND OF THE INVENTION

A. Field of the Invention

The present invention relates to a method for producing a top-emitting OLED (Organic Light Emitting Diode) device, in which an organic layer is prevented from being damaged upon forming of an upper transparent electrode through which light is emitted.

B. Description of the Related Art

Such an OLED device has been subjected to practical use that contains an insulating substrate, such as a glass substrate, having thereon constitutional elements including a lower electrode, a light-emission layer and an upper electrode in this order, operated in the so-called top-emitting structure, in which a reflective metal layer as the lower electrode is formed on the insulating substrate, and light emitted from an OLED device as the light-emission layer is removed through the upper electrode formed of a transparent or translucent material on the side opposite to the substrate. In the top-emitting structure, in general, the lower electrode is used as an anode, and the upper electrode is used as a transparent cathode (see, for example, JP-A-2000-507029).

For attaining the aforementioned structure, it has been important to enhance the electron injection capability of the transparent electrode as the cathode. In the ordinary structure, the cathode is a thin layer formed of a metal, such as aluminum. The work function of, for example, aluminum, is about 3.8 eV, and therefore, an appropriate electron injection electrode, i.e., cathode, is attained in the ordinary structure. However, when a transparent electrode such as ITO, is used as the cathode, the work function is higher, being, for example, about 5 eV for ITO or IZO. Therefore, it is inferior in electron injection capability.

In order to avoid this problem in the top-emitting structure, a small number of proposals have been made in recent years that the lower electrode be used as a cathode, and the upper electrode be used as a transparent anode (see, for example, T. Dobbertin, et al., “Inverted top-emitting organic light-emitting diodes using sputter-deposited anodes,” Applied Physics Letters (USA), vol. 2, No. 2, pp. 284-286)).

Dobbertin et al. denotes difficulty in injection of holes from the upper transparent electrode as a problem arising upon using a transparent anode as the upper electrode. It further notes the difficulty in injection of holes caused by mismatch in work function of the anode.

As a method of reducing the hole injection barrier, it has been proposed that the surface of the anode facing the organic layer be modified (oxidized) through a surface treatment using an ultraviolet ray or plasma. According to the method, the work function of the anode is increased to reduce the hole injection barrier.

The aforementioned method using surface modification can be applied to the case of using a lower electrode as an anode. However, in the case where an upper transparent electrode is used as an anode as in the top-emitting structure shown in Dobberton et al., the method using surface modification cannot be applied to the upper transparent electrode as the anode since the upper transparent electrode is formed directly on the organic film, whereby the hole injection barrier of the upper transparent electrode remains large, which provides considerably small hole injection efficiency. In view of this issue, Dobbertin et al. states that pentacene, which is an organic material having a very high electroconductivity, is formed into a hole injection layer with a thickness of about 40 nm as an underlayer of the upper transparent electrode, thereby enhancing the hole injection efficiency.

In the case where the upper transparent electrode is formed in the top-emission structure shown in Dobbertin et al., i.e., in the case where ITO, IZO or the like is formed into a film as an upper electrode, a sputtering method is generally employed. In this case, however, there is a problem that the organic film as the underlayer, i.e., pentacene as the hole injection layer, is damaged with heat, oxygen radicals and high-energy ions upon sputtering to reduce the hole injection efficiency.

To prevent the reduction in light-emission capability due to damage upon sputtering for forming the upper electrode, there have been such proposals that a metallic thin film, an oxide of which is opaque, such as gold, nickel or aluminum, is formed into a thin film capable of transmitting light having a thickness of from 1 to 20 nm accumulated on the organic layer (see JP-A-2003-77651 (claim 3, paragraph 0040), which corresponds to US-A-2003-45021), and a laminated structure, which contains a first metallic layer to protect from damage on sputtering or for controlling the injection barrier and a second metallic layer of Cr, Ti, Al or the like to control the junction, is inserted between the hole transporting layer and the transparent electrode (see JP-A-2005-122910 (claim 3, paragraphs 0029 and 0034)).

For avoiding the reduction in hole injection efficiency due to damages on sputtering for forming the upper electrode, there have been such proposals that after forming the hole transporting layer, a metallic oxide, such as vanadium oxide or molybdenum trioxide, is vapor-deposited directly thereon to form a hole injection layer (see, for example, JP-A-2005-32618 (paragraph 0042), JP-A-2006-324536 (paragraphs 0032 and 0033), which corresponds to US-A-2006-261333), and JP-A-2005-259550 (paragraphs 0078, 0083 and 0094), which corresponds to US-A-2007-170843).

The present invention is directed to overcoming or at least reducing the effects of one or more of the problems set forth above.

### SUMMARY OF THE INVENTION

Under the circumstances, the invention provides an OLED device having a top-emitting structure containing a lower electrode functioning as a cathode. Formed on the cathode are a light-emission layer containing an organic light emitting material, a hole injection layer and an upper electrode functioning as an anode, in this order, in which the hole injection layer is prevented from being damaged upon forming the upper electrode, thereby attaining high hole injection efficiency.

To attain the aforementioned and other objects, in the OLED device having a light-emission layer between an anode and a cathode according to the production method of the invention, a metallic thin layer capable of forming a transparent electroconductive oxide is inserted as a lower layer under the upper transparent electrode, through which light is taken out, and is oxidized on formation of the upper transparent electrode.

The oxidized metallic thin layer is preferably an electron acceptor in a semiconductor.

The metal, an oxide of which is an electron acceptor in a semiconductor, is not particularly limited, and examples include indium, tin, tungsten, molybdenum, vanadium and ruthenium, depending on the material for the upper transparent electrode. The metallic thin layer preferably has a thickness of from 1 to 5 nm. Upon forming the upper transparent electrode, a film forming method using a plasma formed from gas containing a mixture of argon and oxygen, for example, a plasma CVD method or a sputtering method may be employed. A film forming method using sputtering and an oxygen radical source in combination also may be employed.

By producing a top-emitting OLED device with the method according to the invention, the organic layer can be prevented from suffering damage, such as oxidation, which can occur when forming the upper transparent electrode by a sputtering method, thereby providing an OLED device exhibiting high efficiency and high reliability.

### BRIEF DESCRIPTION OF THE DRAWINGS

The foregoing advantages and features of the invention will become apparent upon reference to the following detailed description and the accompanying FIGURE of drawing which is a schematic cross sectional view showing an OLED device produced according to an embodiment of the invention.

### DETAILED DESCRIPTION OF SPECIFIC EMBODIMENTS

An embodiment of the invention will be described with reference to the schematic cross sectional view in the sole FIGURE of drawing, which shows an OLED device according to the embodiment of the invention.

Substrate 1 may be an insulating flat substrate having a rigidity capable of supporting the structure of the OLED device, and a substrate formed of glass or a resin is generally used for the substrate. In this embodiment, substrate 1 is a glass substrate. Lower electrode 2 is formed as a cathode on glass substrate 1. In this embodiment, a metallic film formed by co-deposition of Mg and Ag is used. The thickness is about 100 nm or more for reflecting light.

In the case where a co-deposition film having a low work function metal doped is applied to electron injection layer 3, the material for lower electrode 2 may be one capable of transporting electrons, thus broadening the options therefor. For example, an Ag single layer and a metallic oxide film, such as ITO and IZO, may be applied. Organic layers including light-emission layer 5 containing an organic light emitting material, i.e., electron injection layer 3, electron transporting layer 4, light-emission layer 5, hole transporting layer 6 and hole injection layer 7, are formed on lower electrode 2. Organic layers 3 to 7 including light-emission layer 5 may be formed of a hole transporting material, an electron transporting material, a fluorescent dye and the like that are ordinarily used in OLED devices.

To obtain blue to blue green light emission, light-emission layer 5 preferably contains a fluorescent whitening agent, such as a benzothiazole compound, a benzoimidazole compound and a benzoxazole compound, a metal-chelate oxonium compound, a styrylbenzene compound, an aromatic dimethylidyne compound or the like.

Examples of the material for electron injection layer 3 include a quinoline derivative (such as an organic metal complex having 8-quinolinol as a ligand), an oxadizaole derivative, a perylene derivative, a pyridine derivative, a pyrimidine derivative, a quinoxaline derivative, a diphenylquinone derivative and a nitro-substituted fluorene derivative. Examples of the material for the electron injection layer 3 also include an alkali metal, an alkaline earth metal, and an oxide, a fluoride, a nitride and a boride thereof, such as LiF.

Examples of the material for electron transporting layer 4 include a metal complex compound (such as Alq₃), an oxadiazole compound and a triazole compound. Examples of the material for hole transporting layer 6 include a starburst amine and an aromatic diamine.

Examples of the material for hole injection layer 7 include a polymer of an aromatic amine compound, a starburst amine or a benzidine amine, and copper phthalocyanine (CuPc).

The thickness of these layers may be those conventionally employed, and electron injection layer 3 in the invention generally has a thickness of from 1 to 5 nm, preferably from 1 to 2 nm, and most preferably 1 nm, to reduce the electric resistance since an inorganic material is used therefor. In the case where an organic material used for electron injection layer 3, the thickness thereof is generally from 1 to 20 nm, and preferably 10 nm. Electron injection layer 3 may not have a homogeneous thickness, but may be formed, for example, in an island form. In the case where electron injection layer 3 is formed in an island form, the maximum height of the islands is designated as the thickness thereof.

The material for metallic thin layer 8 formed on hole injection layer 7 may be a metal capable of forming a transparent electroconductive oxide. The term “transparent oxide” referred herein means an oxide having a visible light transmittance of 90% or more at a thickness of 100 nm. The term “electroconductive oxide” referred herein means an oxide having an electroconductivity of 1×10⁻³ S/m or more at room temperature.

The metal forming the oxide is preferably a metal functioning as an electron acceptor in a semiconductor. The term “electron acceptor” as referred to herein means a material having a work function that is larger than or equivalent to the upper transparent electrode. The metal functioning as an electron acceptor in a semiconductor is not particularly limited, and examples thereof include indium, tin, tungsten, molybdenum, vanadium and ruthenium, at least one of which may be used.

The metal may be formed into a thin layer by a vacuum heating vapor deposition method or an electron beam vapor deposition method, which has been ordinarily employed, and the thickness of the thin layer is preferably from 1 to 5 nm. In the case where the thickness is less than the range, the effect of preventing hole injection layer 7 from being damaged may be reduced, and the thickness exceeds the range, oxidation for forming the transparent oxide with a sputtering gas upon forming upper anode 9 may be insufficient to reduce the transparency. The thickness of metallic thin layer 8 is more preferably less than 2 nm.

When the top-emitting OLED device is thus fabricated in the aforementioned manner, oxygen radicals and high-energy particles generated upon forming the upper transparent electrode functioning as an anode are blocked with the metallic thin layer, and damages of the hole injection layer, such as decomposition of the organic molecular bond, due to oxidation and impact of sputtering particles can be prevented from occurring. Furthermore, advantageously, the oxidative sputtering gas oxidizes the metallic thin layer upon being in contact therewith, and accordingly, a majority of the metallic thin layer is changed to an oxide having transparency and electroconductivity on formation of the upper transparent electrode.

In the case where a metal forming an oxide functioning as an electron acceptor is used in the metallic thin layer, the metal does not impair the hole injection capability but rather enhances the hole injection capability to attain a high hole injection efficiency.

In the case where the metallic thin layer has a certain thickness, it is considered that such a structure may be provided that the surface portion of the metallic thin layer, on which the upper transparent electrode is accumulated, is substantially oxidized, and the ratio of the oxide is gradually decreased in the depth direction, i.e., the metallic thin layer is not completely oxidized. However, when an electron acceptive material is used in hole injection layer 7, or an electron acceptive material is doped as mixture, a high hole injection capability can be attained with high probability even though the metallic thin layer is not completely oxidized.

The method of using the metal as a target material in the invention advantageously increases the film forming rate to provide excellent mass-productivity, as compared to a method of vapor-depositing a metallic oxide itself.

Upper transparent electrode 9 on metallic thin layer 8 is not particularly limited as long as it functions as a transparent electrode, and examples of the material therefor include an oxide containing In, Sn, Zn, Sb and the like, such as indium tin oxide (ITO) and indium zinc oxide (IZO). Upper transparent electrode 9 may be formed by a film forming method using plasma generated from a mixed gas of argon and oxygen, such as a plasma CVD method and a sputtering method. A film forming method using sputtering and an oxygen radical source in combination may also be employed.

In the case where the sputtering method is employed, it is preferred that a prescribed target is used, and a film is formed in an atmosphere containing oxygen. For example, a mixed gas of oxygen and argon may be used as a discharge gas. The ratio of oxygen in the discharge gas is not particularly limited, and for example the molar ratio of (oxygen)/(discharge gas) may be in a range of from 0.01 to 0.05. The lower limit of the ratio (oxygen)/(discharge gas) is more preferably 0.01, and the upper limit thereof is more preferably 0.05, and further preferably 0.02. In the invention, the ratio of oxygen may not be constant during the film formation process, and for example, a discharge gas having a high oxygen ratio is used in the initial stage of film formation for accelerating oxidation of metallic thin layer 8, followed by decreasing the oxygen ratio for forming the transparent electrode after completing the oxidation.

Transparent electrode 9 is formed with a gas containing oxygen, for example, by a sputtering method, whereby metallic thin layer 8 is exposed to oxygen having been activated with plasma, and thus the metallic thin layer 8 is formed into a layer having transparency and electroconductivity.

In this embodiment, metallic thin layer 8 is formed on hole injection layer 7, and then metallic thin layer 8 is oxidized on formation of upper transparent electrode 9. Alternatively, an embodiment may be employed in which a lower anode, a hole injection layer (if required), a hole transporting layer (if required), a light-emission layer, an electron transporting layer (if required) and an electron injection layer (if required) are formed in this order on a substrate, and a metallic thin layer, an oxide of which has a work function that is smaller than or equivalent to an upper transparent cathode, is formed on the electron injection layer, followed by oxidizing the metallic thin layer on formation of the upper transparent cathode.

### Example 1

The FIGURE of drawing is a schematic cross sectional view showing an embodiment of the invention. Mg and Ag were co-deposited as reflective lower cathode 2 at a ratio of 9/1 on substrate 1. Li was formed as electron injection layer 3 to a thickness of 1 nm by a resistance heating vapor-deposition method. Electron injection layer 3 was formed in an island form, as opposed to a film form, since the thickness thereof was as small as 1 nm. Tris(8-hydroxyquinoline) aluminum complex was formed as electron transporting layer 4 to a thickness of 10 nm, and then light-emission layer 5 having a thickness of 30 nm (4,4′-bis(2,2′-diphenylvinyl)biphenyl), hole transporting layer 6 having a thickness of 10 nm (4,4′-bis(N-(1-naphthyl)-N-phenylamino)biphenyl) and hole injection layer 7 having a thickness of 20 nm (copper phthalocyanine) were vapor deposited in this order.

Metallic thin layer 8 was then formed to a thickness of 2 nm by an electron beam vapor deposition method. As a material for forming the metallic thin layer, Mo (work function: about 4.45 eV) was used. A device having metallic thin layer 8 formed thereon was placed in a DC sputtering apparatus, and a transparent anode having a thickness of 100 nm was formed with indium zinc oxide (IZO) (work function: about 4.7 eV) as a target in an oxygen-argon atmosphere ((oxygen)/(oxygen+argon)=0.02 (molar ratio)) to produce a top-emitting OLED device. According to the procedure, metallic thin layer 8 was completely oxidized to an electron acceptive oxide having transparency and electroconductivity. The resulting device exhibited a driving voltage of 8 V and a light-emission efficiency of about 1.5 lm/W.

### Example 2

A top-emitting device was produced in the same manner as in Example 1 except that a metallic thin layer having a thickness of 10 nm was formed with Ru (ruthenium). In the resulting device, the metallic thin layer had such a structure that the surface portion thereof in contact with the upper transparent electrode was substantially oxidized, and the ratio of the oxide was gradually decreased in the depth direction, as revealed by XPS. The resulting device exhibited a driving voltage of 8 V and a light-emission efficiency of about 1.5 lm/W, which showed that the structure of the oxidized layer did not adversely affect the hole injection capability.

### Example 3

A reflective lower anode (formed of Mg and Ag) was formed on a substrate in an ordinary method. A hole injection layer having a thickness of 20 nm (copper phthalocyanine), a hole transporting layer having a thickness of 10 nm (4,4′-bis(N-(1-naphthyl)-N-phenylamino)biphenyl), a light-emission layer having a thickness of 30 nm (4,4′-bis(2,2′-diphenylvinyl)biphenyl) and electron transporting layer 4 having a thickness of 10 nm (tris(8-hydroxyquinoline) aluminum complex) were formed in this order, and an electron injection layer was formed to a thickness of 1 nm in an island form but not in a film form.

Metallic thin layer 8 was then formed to a thickness of 2 nm by an electron beam vapor deposition method. As a material for forming the metallic thin layer, V (vanadium) was used. A device having metallic thin layer 8 formed thereon was placed in a DC sputtering apparatus, and an upper transparent anode having a thickness of 100 nm was formed with indium zinc oxide as a target to produce a top-emitting OLED device. The resulting device exhibited a driving voltage of 8 V and a light-emission efficiency of about 1.6 lm/W.

### Comparative Example 1

A top-emitting device was produced in the same manner as in Example 1 except that the metallic thin layer was not inserted. The resulting device exhibited a light-emission efficiency of about 1/10 of that of the OLED device obtained in Example 1, and leak current was observed, thereby failing to attain sufficient characteristics as a light-emission device.

### Comparative Example 2

A top-emitting device was produced in the same manner as in Example 1 except that a metallic thin layer was formed with Al to a thickness of 5 nm. The resulting device suffered in transmittance of visible light due to oxidation of the Al metallic thin layer on formation of the transparent anode. The device exhibited a driving voltage of 8 V and a light-emission efficiency of about 0.8 lm/W.

Thus, an organic light emission device has been described according to the present invention. Many modifications and variations may be made to the techniques and structures described and illustrated herein without departing from the spirit and scope of the invention. Accordingly, it should be understood that the methods and devices described herein are illustrative only and are not limiting upon the scope of the invention.

This application is based on and claims priority to Japanese Patent Application 2008-107826, filed on Apr. 17, 2008. The disclosure of the priority application in its entirety, including the drawings, claims, and the specification thereof, is incorporated herein by reference.

What is claimed is:

1. A method for producing a top-emitting organic light emitting diode device comprising a substrate having provided thereon at least a lower electrode, an organic layer containing a light-emission layer, and an upper transparent electrode, the method comprising the steps of:
forming the organic layer, then
forming a metallic thin layer capable of forming a transparent electroconductive oxide; and then
oxidizing the metallic thin layer on formation of the upper transparent electrode.

2. The method for producing a top-emitting organic light emitting diode device as claimed in claim 1, wherein the oxidized metallic thin layer is an electron acceptor.

3. The method for producing a top-emitting organic light emitting diode device as claimed in claim 2, wherein the metallic thin layer to be oxidized contains at least one element selected from the group consisting of indium, tin, tungsten, molybdenum, vanadium and ruthenium.

4. The method for producing a top-emitting organic light emitting diode device as claimed in claim 1, wherein the metallic thin layer has a thickness of from 1 to 5 nm.

5. The method for producing a top-emitting organic light emitting diode device as claimed in claim 1, wherein the metallic thin layer has a thickness of from 1 to 2 nm.

6. The method for producing a top-emitting organic light emitting diode device as claimed in claim 1, wherein the upper transparent electrode is formed by a film forming method using plasma formed from a gas containing a mixture of argon and oxygen.

7. The method for producing a top-emitting organic light emitting diode device as claimed in claim 1, wherein the upper transparent electrode is formed by a film forming method using sputtering and an oxygen radical source in combination.

8. A top-emitting organic light emitting diode device comprising a substrate having provided thereon in this order at least a lower electrode, an organic layer containing a light-emission layer, and an upper transparent electrode, wherein the top-emitting organic light emitting diode device is produced by a method including the steps of forming the organic layer, then forming a metallic thin layer having a thickness of from 1 to 5 nm capable of forming a transparent electroconductive oxide; and then oxidizing the metallic thin layer on formation of the upper transparent electrode.

9. A top-emitting organic light emitting diode device comprising a substrate having provided thereon in this order at least a lower electrode, an organic layer containing a light-emission layer, a metallic thin layer having a thickness of from 1 to 5 nm, and an upper transparent electrode, wherein at least the surface portion of the metallic thin layer that is in contact with the upper transparent electrode is oxidized.

10. A top-emitting organic light emitting diode device as claimed in claim 9, wherein the degree of oxidation in the metallic thin film decreases in the depth direction, with the highest degree of oxidation being adjacent the upper transparent electrode.

11. A top-emitting organic light emitting diode device as claimed in claim 9, wherein the metallic thin layer has a thickness of from 1 to 2 nm.

12. A top-emitting organic light emitting diode device as claimed in claim 9, wherein the oxidized metallic thin layer is an electron acceptor.

13. A top-emitting organic light emitting diode device as claimed in claim 12, wherein the metallic thin layer contains at least one element selected from the group consisting of indium, tin, tungsten, molybdenum, vanadium and ruthenium.
